(19) United States
(12) Patent Application Publication
(10) Pub. No.: US 2016/0313388 A1
(43) Pub. Date: Oct. 27, 2016

(54) NONCONTACT SENSING OF MAXIMUM OPEN-CIRCUIT VOLTAGES

(71) Applicant: LEHIGHTON ELECTRONICS, INC., Lehighton, PA (US)

(72) Inventor: William H. Howland, Wexford, PA (US)

(73) Assignee: LEHIGHTON ELECTRONICS, INC., Lehighton, PA (US)

(21) Appl. No.: 15/104,281

(22) PCT Filed: Dec. 21, 2014
(86) PCT No.: PCT/US14/71770

§ 371 Date: Jun. 14, 2016

Related U.S. Application Data
(60) Provisional application No. 61/919,779, filed on Dec. 22, 2013.

(51) Int. Cl. G01R 31/265; H02S 50/15

(52) U.S. Cl. CPC G01R 31/2656; H02S 50/15

(57) ABSTRACT

An apparatus for noncontact sensing of a voltage response characteristic and/or maximum open-circuit voltage (MOCV) of photovoltaic semiconductor specimens includes a high intensity wide spectrum light source adapted to emit light through a conductive probe tip; the conductive probe tip is situated in spatial relationship with a vacuum chuck to form a capacitive specimen wafer interrogation space upon which specimen wafers are located; the high intensity light source emits light through the conductive probe tip, said light impinges a specimen wafer located within the interrogation space, and voltage response across the probe tip, wafer interrogation space, and vacuum chuck is amplified and recorded.

### CROSS REFERENCE TO RELATED APPLICATIONS

This application claims priority to U.S. Provisional Patent Application No. 61/919,779, filed Dec. 22, 2013 and incorporates the same by reference as if set forth herein in its entirety.

### STATEMENT AS TO FEDERALLY SPONSORED RESEARCH

Not applicable.

### BACKGROUND OF INVENTION

### Field of Invention

The present disclosure relates to a noncontact measurement apparatus, system, and method of use. In particular, this disclosure concerns an apparatus, system, and related methods for noncontact measurement of an electrical response of a photovoltaic semiconductor specimen to a flash, pulse, or burst of light.

In the processing of photovoltaic materials, strict quality control of the material characteristics is necessary to obtain a quality product. As such, various instruments are used to measure material characteristics throughout processing. A key consideration associated with employment of a particular instrument is speed of use. There is a need to rapidly obtain quality control measurements to avoid slowing down production or examination times. Another key consideration requires the use of nondestructive methods to monitor the material characteristics. Destructive methods are time intensive and preclude subsequent use of the specimen.

The photovoltaic's electrical response to incident light can be used for the purpose of characterizing one or more material characteristics during or after processing. Examples include identifying built in potential, dopant concentration of one or more layers, changes in material alloy composition, changes in GaN based polarization and identifying mechanical damage to the material such as fracturing.

It is therefore desirable, and an object of the invention, to have a device, system, and method that enables rapidly inducing a photovoltaic material to incident illumination, monitoring the electrical response by nondestructive means, and correlating the electrical response with a material characteristic of the photovoltaic specimen.

### SUMMARY OF INVENTION

The instant invention is directed to an apparatus for noncontact sensing of the maximum open-circuit voltage (MOCV) of photovoltaic semiconductor specimens. The apparatus includes a high intensity wide spectrum light source adapted to emit light through a conductive probe tip. The conductive probe tip is situated in spatial relationship with a vacuum chuck to form a capacitive specimen wafer interrogation space upon which specimen wafers are located. The high intensity light source emits light through the conductive probe tip. Said light impinges a specimen wafer located within the interrogation space. A voltage response across the probe tip, wafer interrogation space, and vacuum chuck is amplified and recorded. MOCV is identified from the voltage response. In an embodiment of the present invention, the conductive probe tip is coated with, formed from, or includes a transparent conducting oxide. Preferably, the conductive probe tip is a conductive mesh which is transparent to UV light as well as visible wavelengths.

Further disclosed is a method for measuring work function differences across semiconductor-semiconductor, semiconductor-insulator or semiconductor-metal interfaces in a semiconductor product (or monitor) wafer. A high intensity varying light is applied to the specimen wafer. An open-circuit voltage characteristic for said wafer is measured in response to said light. The open-circuit voltage characteristic is indicative of work function difference characteristic of a set of one or more of said type work functions. A doping characteristic for at least one of said type interfaces is determined utilizing said maximum open-circuit voltage characteristic and a known value relating to work function on one side of the interface.

Also disclosed is a method for contactless characterization of the emitter and base doping concentrations of a specimen semiconductor p-n junction. A specimen semiconductor is located between a conductive probe tip and a vacuum chuck. Light is emitted through the conductive probe tip onto the specimen, and a voltage response is sensed at the conductive probe tip as (before, while, and after) the light emitted through the mesh plate impinges the specimen.

Additional features, advantages, and embodiments of the invention may be set forth or apparent from consideration of the following detailed description. Moreover, it is to be understood that both the foregoing summary of the invention and the following detailed description are exemplary and intended to provide further explanation without limiting the scope of the invention.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detailed description serve to explain the principles of the invention. In the drawings:

FIG. 1 is a view in perspective of a bench top version of the system according to embodiment of the present invention;

FIG. 2 is a view in perspective of an automated rotary mapper version of the system an embodiment of the present invention;

FIG. 3 is an exploded view in perspective showing the probe tip, interrogation space, specimen, and vacuum chuck according to an embodiment of the present invention;

FIG. 4 is a bottom view in perspective of the probe tip according to an embodiment of the present invention;

FIG. 5 is a bottom view in perspective of the probe tip according to an embodiment of the present invention;

FIG. 6 is a bottom view in perspective of the probe tip according to an embodiment of the present invention; and

FIG. 7 is a bottom view in perspective of the probe tip according to an embodiment of the present invention.

### DETAILED DESCRIPTION OF THE EMBODIMENTS

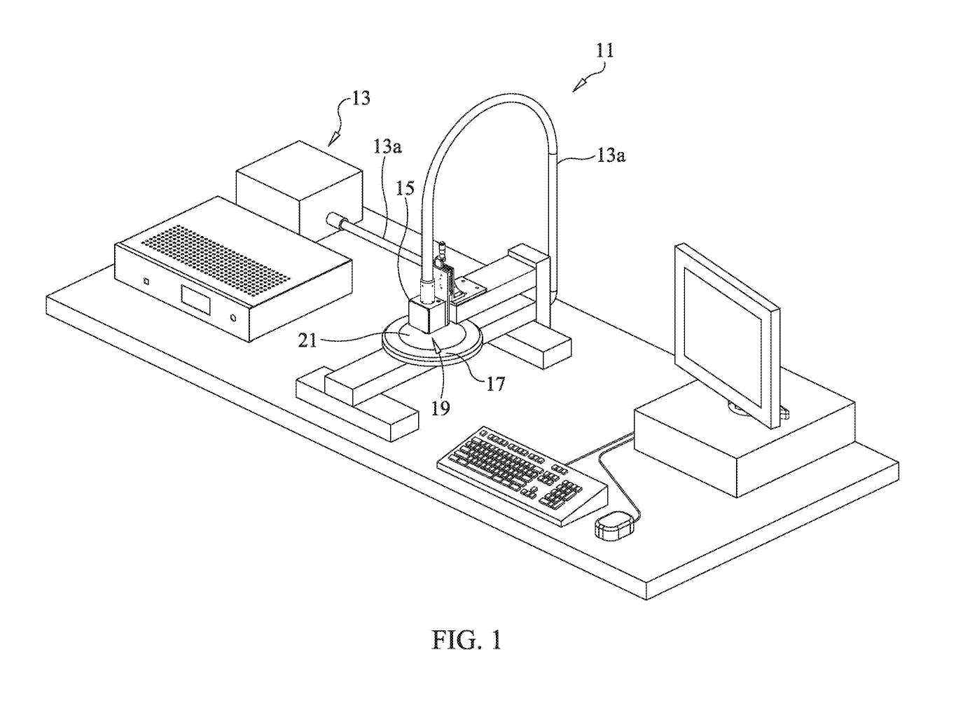

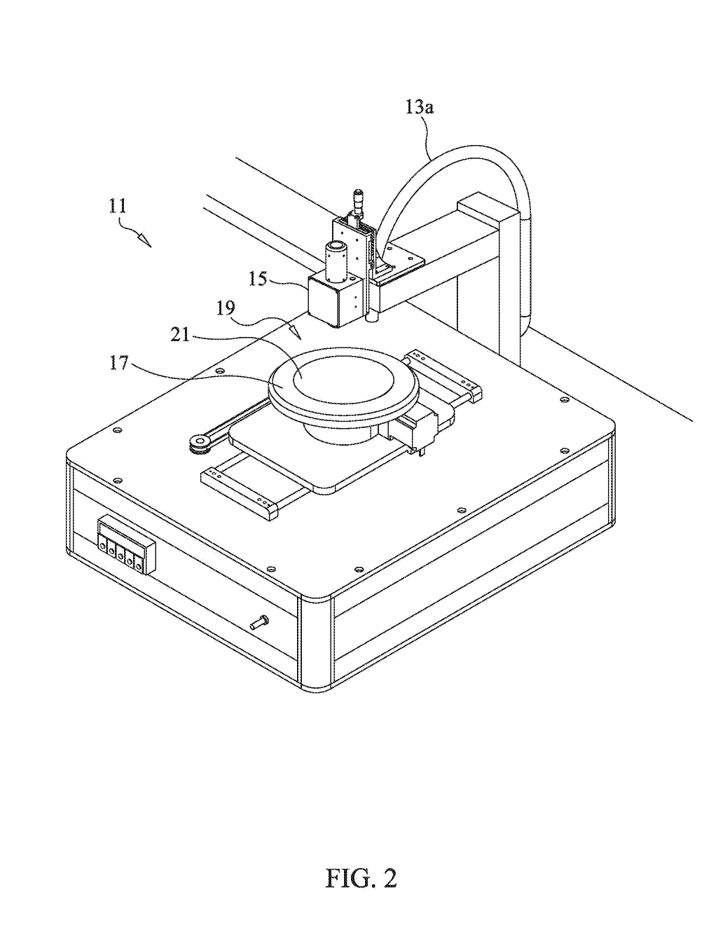

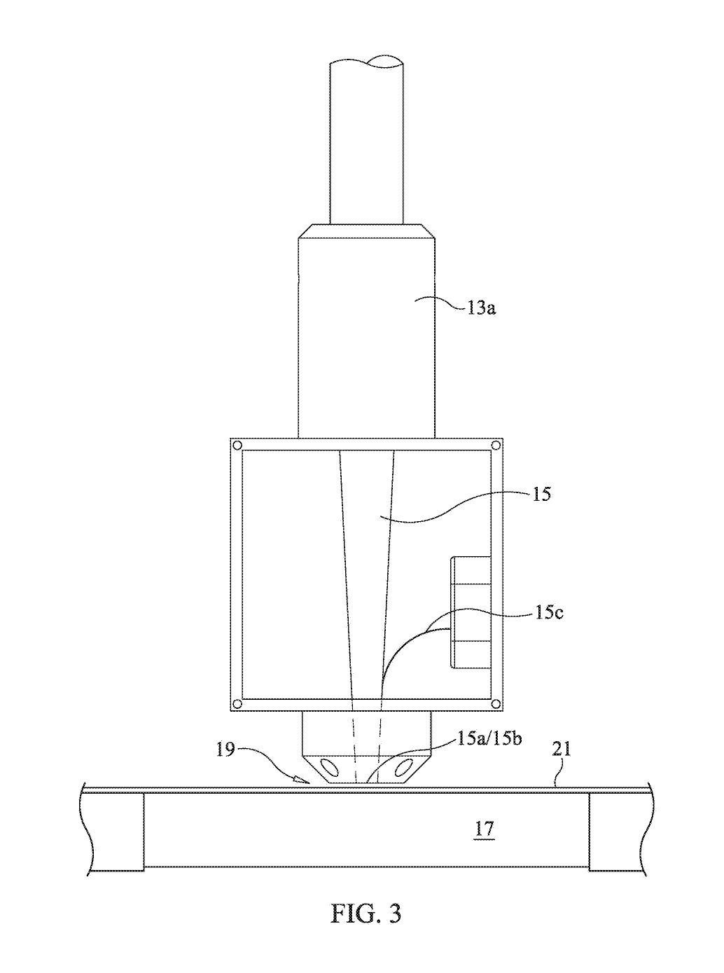

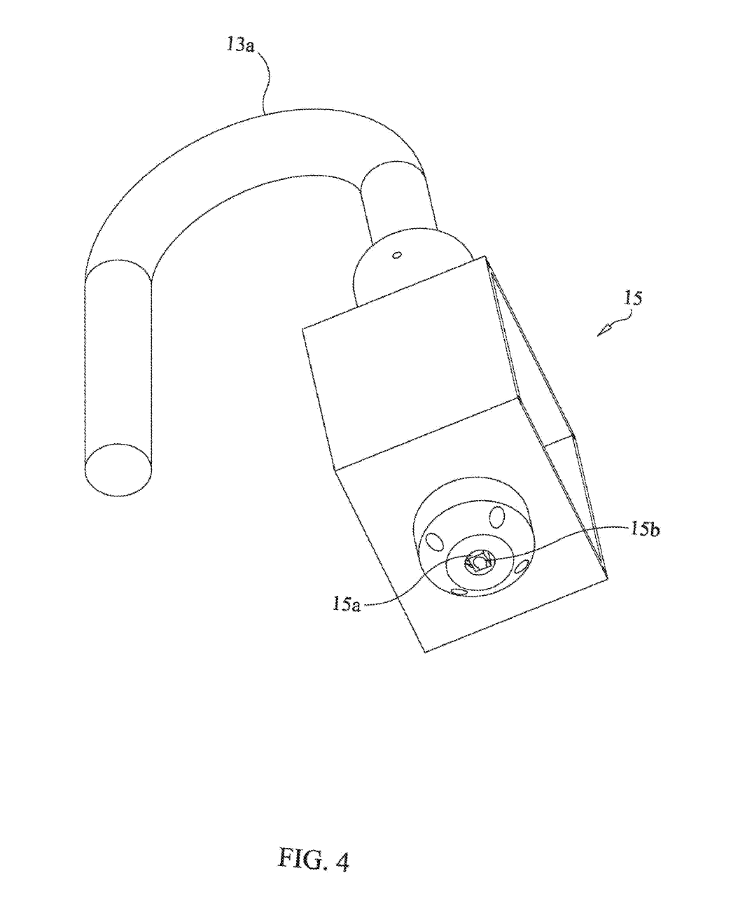

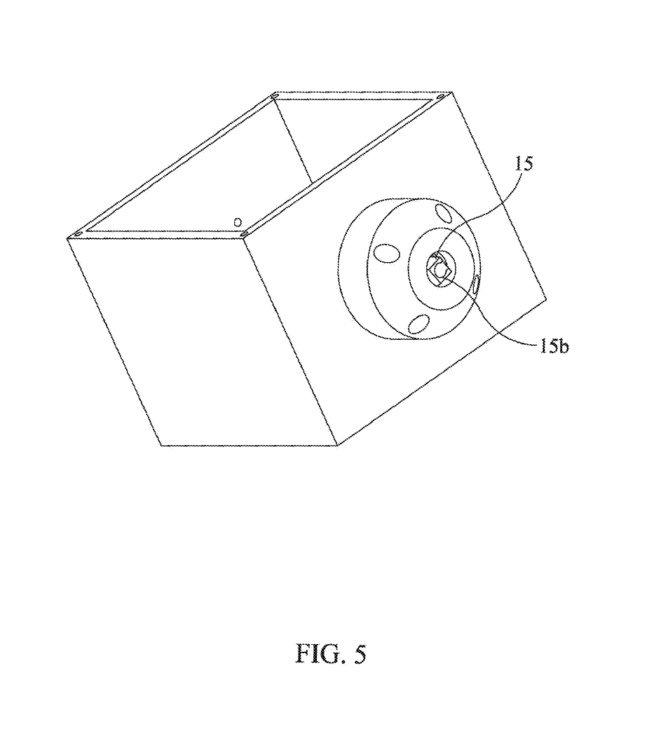

Referring now to the Figures in general, and specifically to FIG. 1-FIG. 6, embodiments of the present invention are directed to an apparatus 11 for noncontact sensing of a voltage response characteristic and/or maximum open-circuit voltage (MOCV) of photovoltaic semiconductor specimens. In particular, the apparatus 11 is directed (a) cause the impingement of light onto a photovoltaic specimen under study, and (b) to record a voltage response characteristic occurring in response to the impingement of light onto the photovoltaic specimen 21. Photovoltaic semiconductor specimens are understood as specimens with at least one interface comprising two materials with differing workfunctions. The two materials can be (1) metal/semiconductor, (2) semiconductor/semiconductor, (3) semiconductor/insulator or (4) insulator/insulator.

The apparatus 11 includes a light source 13 adapted to emit a flash, pulse, or burst of light through a conductive probe tip 15. The conductive probe tip 15 is situated in spatial relationship with a vacuum chuck 17 to form a capacitive specimen wafer interrogation space 19 upon which specimen wafers 21 are located. The probe tip 15 and the vacuum chuck 17 form parallel plates of a capacitor, and are approximately located between 0.003 and 0.005 inches apart when the measurement is taken. The interrogation space 19 containing the specimen wafer 21 becomes the dielectric of the capacitor. This spatial arrangement of the specimen wafer 21 relative to the probe tip 15 and the vacuum chuck 17 allows for the measurement of a voltage across the capacitor. That voltage is indicative of, or correlate-able with, a particular physical and or electrical characteristic of the specimen wafer 21 under interrogation.

Further, when the specimen wafer 21 under interrogation is illuminated, the measurement of a time voltage response across the capacitor is indicative of one or more physical and or electrical characteristics of the specimen wafer 21. The phrase “time voltage response” is understood to mean before, during, and after illumination of the specimen wafer 21. An exemplary graphically representation of a time voltage response is a voltage/time plot or curve. As used herein, MOCV is understood as one characteristic that is obtainable from use of the apparatus 11. Open Circuit Voltage Decay (OCVD) is another exemplary characteristic that is obtainable from use of the apparatus 11.

The light source 13, preferably, is a high intensity wide spectrum light source such as a pulsed xenon flash lamp. The flash lamp shall produce microsecond to millisecond duration pulses of broadband light of high radiant intensities, and is capable of operating at high repetition rates to generate light over a continuous spectrum from ultraviolet to infrared. One such flash lamp is the Perkin Elmer model FX-4400. An alternate to the xenon flash lamp is a high intensity LED solution capable of pulsing white light.

In a preferred embodiment, the light source 13 is remotely located and electrically isolated in a separate enclosure from the probe tip 15 and vacuum chuck 17 to avoid any electrostatic interference created by the light source 13. Light conducting guides 13a, cladded glass rods, or the like are utilized to conduct the light emitted from the light source 13 to the probe tip 15.

In an embodiment of the present invention, the probe tip 15 is a quartz pipe having a distal end 15a nearest to the interrogation space 19. The light from the source 13 is conducted through the probe tip 15 and exits the distal end 15a. The distal end 15a of the probe tip 15 has a light transmissive conductive layer 15b, which, as discussed herein, acts as one plate of the capacitor. Light from the source 13 travels through the conductive layer 15b onto the specimen 21.

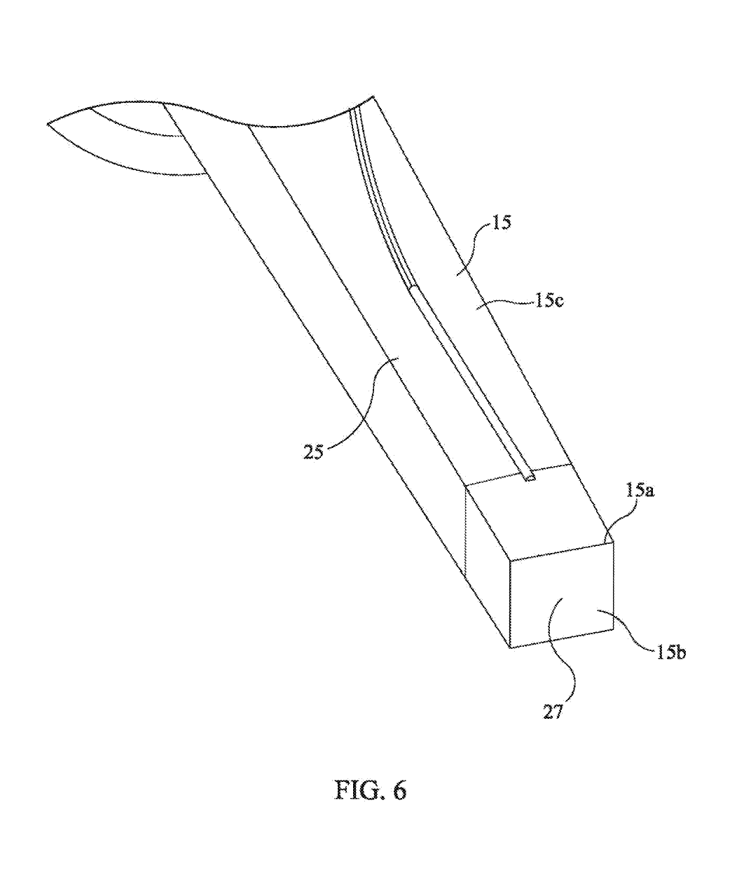

Referring to FIG. 6, one material that is used for the conductive layer 15b, that is capable of allowing the passage of light, is a transparent conducting oxide. One such transparent conducting oxide is indium tin oxide (ITO), which has a typical composition of 91% SnO₂ and 9% In₂O₃. Sputtering is a common method used to deposit ITO onto the distal end 15a of the probe tip 15 at a preferred thickness of 2000 Angstrom. A lead wire 15c connecting the conductive layer 15b to a measurement circuit is connected by means of a conducting epoxy. ITO, however has a limit to the wavelength (and the corresponding energy) of light that can pass through the medium. ITO can pass roughly 3 eV.

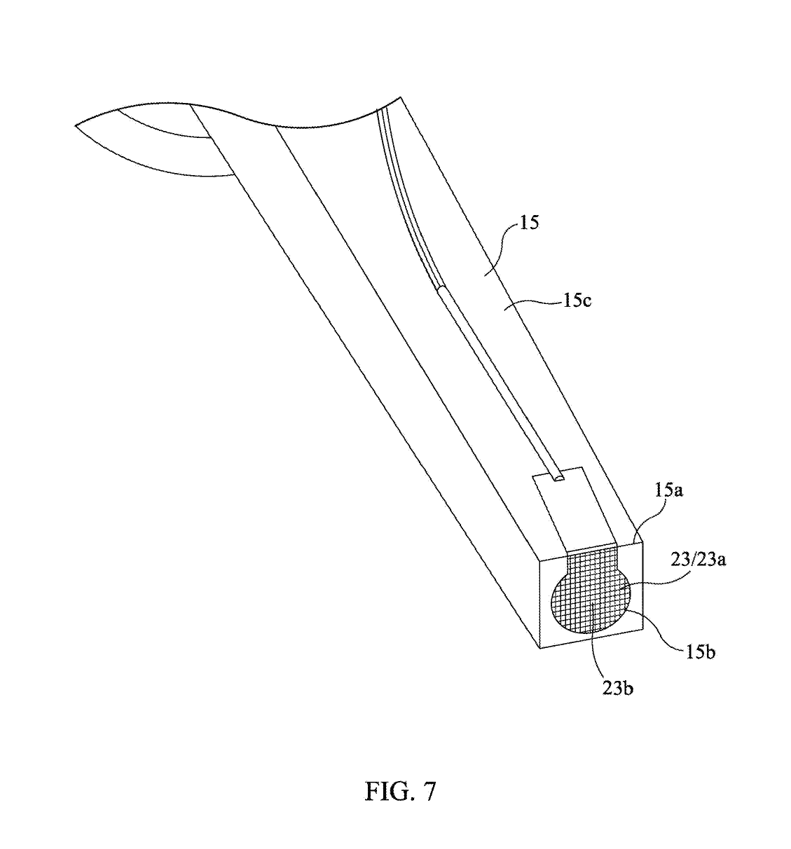

In a preferred embodiment, the conductive layer 15b of the probe tip 15 is a conductive mesh 23. The conductive mesh 23 is generally flat and comprises a grid 23a of conductive material (fibers or filaments) that form a plurality of interstices 23b or apertures (holes) that are sufficiently large in size to allow any wavelength of light to pass. An example mesh is a grid of conductive strands or fibers having a 100 mesh size. However, other mesh dimensions are employable, provided the mesh can pass any wavelength of light and continue to function as a capacitive plate. Cyanoacrylate glue, or a functional equivalent, is used around the perimeter of the conductive layer 15b to fix the conductive layer 15b to the probe tip 15 at its distal end 15a. FIG. 7 shows the conductive mesh 23 in a scale the is disproportionately larger relative to the probe tip 15 to illustrate a zoom in view of one structure of the conductive mesh 23.

In an embodiment of the present invention, there is disclosed a method for measuring work function differences across semiconductor-semiconductor, semiconductor-insulator or semiconductor-metal interfaces in a semiconductor product (or monitor) specimen wafer. The method includes applying high intensity varying light to said wafer. An open-circuit voltage characteristic is measured for said wafer as it responds to said light. The measured open-circuit voltage characteristic is indicative of, and/or relatable to, a work function difference characteristic of a set of the one or more of work functions of the interface. A doping characteristic is determined for at least one of said type interfaces utilizing the measured open-circuit voltage characteristic and also utilizing a known value of work function on one side of the interface.

In addition to extracting the doping from the built in potential measurement, there are other uses of this parameter. These include the following:
For solar cell device structures, the built in potential is highly sensitive to
   p-n junction shunting after diffusion and ion implantation,
   surface charge changes after texturization,
   surface charge changes after anti-reflection coating deposition,
High brightness, and UV multiple quantum well LEDs
   Changes in substrate doping concentration
   Thickness and alloy composition changes in buffer regions,
   Variations in emitter and base doping
   Thickness and alloy composition changes in the multiple quantum well region
For HEMT structure
   Changes in substrate doping concentration
   Variations in thickness and alloy composition in buffer layers,
   Changes in channel layer doping and 2 DEG carrier concentration
   Changes in barrier layer alloy composition and thickness
   Variations in capping layer doping, thickness and alloy composition

In an embodiment of the present invention, the step of applying high intensity varying light to said wafer includes emitting a burst of light through a conductive probe tip 15. The conductive probe tip 15 is situated in spatial relationship with a vacuum chuck 17 to form a specimen wafer interrogation space 19 upon which specimen wafers 21 are located.

In a preferred embodiment, the step of “measuring an open-circuit voltage characteristic” further including measuring a time voltage response measured across the conductive probe tip 15, interrogation space 19 containing the specimen wafer 21, and vacuum chuck 17.

In a preferred embodiment, the step of “determining a doping characteristic” includes utilizing known analytical formulas that relate built in potential to doping for a specific interface having optimum desired dopant characteristics, upon which the open-circuit voltage is compared and correlated.

An example includes the relationship between non-degenerately doped solar cell p-n junctions or silicon photodetectors in which case the standard text book formula E1 given below applies. Simon M. Sze, “Physics of Semiconductor Device”, Publisher: Wiley-Interscience; 3 edition (Oct. 27, 2006). Using these applications, typically small corrections for the Dember potential are required, but the standard textbook formula of E1 works quite well.

Alternately, the step of “determining a doping characteristic” includes utilizing empirical results of dopant concentration from known samples having known dopant concentrations, and comparing and correlating the corresponding time voltage response with dopant concentration. For example, for MQW LEDs, potential changes due to interfacial polarization as well as potential changes at for example substrate/buffer layer interfaces must be accounted for and can complicate the extraction of doping. For these more complicated applications, calibration of the OCV method must take place based on a particular device design, parameter selection etc.

A further alternate of “determining a doping characteristic” includes utilizing numerical modeling using TCAD to correlate the corresponding time voltage response with dopant concentration. TCAD device models are typically available (Reference Silvaco or Synopsis) for HBLEDs, UVLEDS, GaN/AlGaN based HEMT structures and most any solar cell design.

### Example Methodology:

By example, and not intended to be limiting, the noncontact method below is utilized to characterize emitter and base doping concentrations of a specimen semiconductor p-n junction. This methodology is one example of use of the apparatus 11, and methods disclosed herein, for a simple p-n junction. For each device type, there are different mathematical expressions that model the specimen based on its material properties and structure (or intended material propertied and structure). The example given here is the most basic/textbook expression available. The applications of the invention extend beyond this example and with more complex semiconductor structures.

A specimen semiconductor 21 is located between a conductive probe tip 15 and a vacuum chuck 17. Light is emitted through the conductive probe tip 15 onto the specimen 21, and a voltage response is sensed at the conductive probe tip 15 as (before, while, and after) the light emitted through the conductive probe tip 15 impinges the specimen 21.

In an embodiment of the present invention method, the conductive probe tip 15 is a quartz pipe 25 that has a coating 27 of a transparent conducting oxide at a distal end 15a nearest to the interrogation space 19. Preferably, the probe tip 15 is tapered (to allow more light to be captured at the pipe entrance, while increasing the light density at the pipe exit. The light is conducted through the tapered quartz pipe 25 and through the coating 27 to impinge the specimen 21. Referring to FIG. 6, the distal end 15a of the probe tip 15 is coated some distance up the sides with the coating 27.

In a preferred embodiment of the present invention method, the conductive probe tip 15 includes a conductive mesh 23 at the distal end 15a. Light (UV through infrared) passes through the conductive mesh 23 to impinge the specimen 21. The conductive mesh 23 is generally flat and comprises a grid 23a of conductive material (fibers or filaments) that form a plurality of interstices 23b or apertures (holes) that are sufficiently large in size to allow any wavelength of light to pass.

Using the vacuum chuck 17 as a return contact, the voltage response across the conductive probe tip 15 and the vacuum chuck 17 is amplified and recorded. A measured open-circuit voltage (OCVₘₑₐₛ) is identified from the voltage response. A measured built-in potential (Vbiₘₑₐₛ) is obtained by modifying the OCVₘₑₐₛ to correct for one or more of preamp gain, incomplete photo-flattening, Dember potential, front surface photovoltage, back surface photovoltage, and/or polarization effects (relating to multiple quantum well structures).

Eddy current measurements (Eddyₘₑₐₛ) are obtained and recorded for the specimen. Further, some or all of the following specimen parameters are obtained: thickness and mobility information for the emitter and base regions, respectively (tₙ μₙ tₚ μₚ).

An iterative method is employed to incrementally change emitter dopant concentration (N_{D}) and base dopant concentration (N_{A}) to solve the following expressions until convergence is obtained between Vbi_{calc} and measured built-in potential (Vbiₘₑₐₛ)
(a) an Eddy Expression (E2) that relates base dopant concentration (N_{A}) to Eddy current (Eddy or Eddyₘₑₐₛ) with emitter dopant concentration (N_{D}), emitter thickness (tₙ), emitter mobility (μₙ), base thickness (tₚ), and base mobility (μₚ), and
(b) a Vbi_{calc} Expression (E1) that relates calculated built-in potential (Vbi_{calc}) to emitter dopant concentration (N_{D}) and base dopant concentration (N_{A});

The emitter dopant concentration (N_{D}) and the base dopant concentration (N_{A}) that results at convergence from the iterative method step is then recorded.

A Vbi_{calc} Expression (E1) relates calculated built-in potential (Vbi_{calc}) to emitter dopant concentration (N_{D}) and base dopant concentration (N_{A}):

$${Vbi}_{CALC} = \frac{kT}{q} \cdot ln [ \frac{{N}_{A} {N}_{D}}{{n}_{i}^{2}} ] \qquad ( E1 )$$

An Eddy Expression (E2) is derived to relate Eddy current (Eddy or Eddyₘₑₐₛ) with emitter dopant concentration (N_{D}), emitter thickness (tₙ), emitter mobility (μₙ), base dopant concentration (N_{A}), base thickness (tₚ), and base mobility (μₚ). The Eddy Expression (E2) is solved for the base dopant concentration (N_{A}).

$${N}_{A} = \frac{Eddy - {qN}_{D} {μ}_{n} {τ}_{n}}{q {μ}_{p} {τ}_{p}} \qquad ( E2 )$$

Where Eddy is defined as the measured eddy current sheet resistance.

This results in two equations (E1 and E2) with each equation sharing the two unknown values of N_{A} and N_{D}. Solution of the two equations is accomplished by iteration. In an exemplary embodiment, iteration is accomplished as follows.

Iteration Step: The emitter dopant concentration (N_{D}) is guessed (N_{D-ith guess}). The guess (N_{D-ith guess}) is inserted into the Eddy Expression (E2) to provide base dopant concentration guess (N_{A-ith guess}). N_{D-ith guess} and N_{A-ith guess} are both inserted into the Vbi_{calc} Expression (E1) to obtain Vbi_{calc-ith guess}. Vbi_{calc-ith guess} is compared with the measured built-in potential (Vbiₘₑₐₛ) and ith deviation is obtained (diff−_{ith-guess}).

Iteration Step above is performed with a first guess resulting in Vbi_{calc 1st guess} and diff−_{1st guess}. Next, Iteration Step is repeated with a second guess (N_{D-2nd guess}) for N_{D}, and Vbi_{calc-1st guess} and diff−_{2nd guess} is obtained.

Convergence Check Step: If the diff−_{ith-guess} is less than diff−_{i-1 guess}, then N_{D-ith guess} is converging toward the correct solution for emitter dopant concentration (N_{D}). Conversely, if the diff−_{ith guess} is greater than diff−_{i-1 guess}, then N_{D-ith guess} is diverging from the correct solution for emitter dopant concentration (N_{D}).

The Convergence Check Step above is performed to identify convergence or divergence. If the current guess (N_{D-ith guess}) is converging, the Iteration Step and Convergence Check Step are repeated, incrementally changing the emitter dopant concentration guess to maintain converging results until the diff−_{ith-guess} reaches convergence (predetermined tolerance level).

The N_{D-ith guess} that corresponds to the point of convergence is the solved emitter dopant concentration for the specimen. Similarly, the corresponding N_{A-ith guess} that is calculated from the second equation using N_{D-ith guess} (that corresponds to the point of convergence) is the solution for base dopant concentration of the specimen.

Although particular embodiments of the invention have been described in detail herein with reference to the accompanying drawings, it is to be understood that the invention is not limited to those particular embodiments, and that various changes and modifications, including the omission of steps or the interchangeability of the order of steps, may be effected therein by one skilled in the art without departing from the scope or spirit of the invention.

1. An apparatus for noncontact sensing of the maximum open-circuit voltage (MOCV) of photovoltaic semiconductor specimens, comprises:
a high intensity wide spectrum light source adapted to emit light through a conductive probe tip, the transparent, conductive probe tip being situated in spatial relationship with a vacuum chuck to form a specimen wafer interrogation space upon which specimen wafers are located,
wherein the high intensity light source emits light through the transparent, conductive probe tip, which said light impinges a specimen wafer located within the interrogation space, and voltage response at the probe tip is amplified and recorded, and MOCV is identified from the voltage response.

2. The apparatus of claim 1, wherein the conductive probe tip is coated with, formed from, or includes a transparent conducting oxide.

3. The apparatus of claim 1, wherein the conductive probe tip is a conductive mesh.

4. The apparatus of claim 3, wherein the conductive probe tip comprises a grid of conductive material that forms a plurality of interstices or apertures (holes) that are sufficiently large in size to allow any wavelength of light to pass.

5. A method for contactless characterization of the emitter and base doping concentrations of a specimen semiconductor p-n junction comprises the following steps:
locating a specimen semiconductor between a conductive probe tip and a vacuum chuck,
emitting light through the conductive probe tip onto the specimen, and
sensing a voltage response at the conductive probe tip as (before, while, and after) the light emitted through the mesh plate impinges the specimen.

6. The method of claim 5, wherein the conductive probe tip is coated with, formed from, or includes a transparent conducting oxide.

7. The method of claim 5, wherein the conductive probe tip is a conductive mesh.

8. The method of claim 7, wherein the probe tip comprises a grid of conductive material that forms a plurality of interstices or apertures (holes) that are sufficiently large in size to allow any wavelength of light to pass.

9. The method of claims 5-8, further including the steps of:
amplifying and recording the voltage response,
identifying a measured open-circuit voltage (OCVₘₑₐₛ) from the voltage response, and
obtaining a measured built-in potential (Vbiₘₑₐₛ) by modifying the OCVₘₑₐₛ to correct for one or more of preamp gain, incomplete photo-flattening, Dember potential, front surface photovoltage, back surface photovoltage, polarization effects (relating to multiple quantum well structures).

10. The method of claim 9, further including the steps of:
obtaining and recording eddy current measurements (Eddyₘₑₐₛ) for the specimen,
obtaining some or all of thickness and mobility information for the emitter and base regions, respectively (tₙ μₙ tₚ μₚ), and
employing an iterative method incrementally changing emitter dopant concentration (N_{D}) and base dopant concentration (N_{A}) to solve the following expressions until convergence is obtained between Vbi_{calc} and measured built-in potential (Vbiₘₑₐₛ):
(c) an Eddy Expression (E2) that relates base dopant concentration (N_{A}) to Eddy current (Eddy or Eddyₘₑₐₛ) with emitter dopant concentration (N_{D}), emitter thickness (tₙ), emitter mobility (μₙ), base thickness (tₚ), and base mobility (μₚ), and
(d) a Vbi_{calc} Expression (E1) that relates calculated built-in potential (Vbi_{calc}) to emitter dopant concentration (N_{D}) and base dopant concentration (N_{A}); and
recording the emitter dopant concentration (N_{D}) and the base dopant concentration (N_{A}) that results at convergence from the iterative method step.

11. A method for measuring work function differences across semiconductor-semiconductor, semiconductor-insulator or semiconductor-metal interfaces in a semiconductor product (or monitor) wafer, said method comprising the following steps:
applying high intensity varying light to said wafer,
measuring an open-circuit voltage characteristic for said wafer in response to said light, said open-circuit voltage characteristic being indicative of work function difference characteristic of a set of one or more of said type functions, and
determining a doping characteristic for at least one of said type interfaces from said maximum open-circuit voltage and known value of workfunction on one side of the interface.

12. The method of claim 11, the step of applying high intensity varying
light to said wafer includes emitting light through a conductive probe tip, the conductive probe tip being situated in spatial relationship with a vacuum chuck to form a specimen wafer interrogation space upon which specimen wafers are located.

13. The method of claim 12, the step of “measuring an open-circuit voltage characteristic” further including measuring a time voltage response across the conductive probe tip, interrogation space, and vacuum chuck.

14. The method of claim 13, the step of “determining a doping characteristic” includes utilizing known analytical formulas that relate built in potential to doping for a specific interface having optimum desired dopant characteristics, upon which the open-circuit voltage is compared.

15. The method of claim 13, the step of “determining a doping characteristic” includes utilizing empirical results of dopant concentration from known samples, and comparing and correlating the corresponding time voltage response with dopant concentration.

16. The method of claim 13, the step of “determining a doping characteristic” includes utilizing mathematical models to correlate the corresponding time voltage response with dopant concentration.
